(19) United States
(12) Patent Application Publication
(10) Pub. No.: US 2003/0010996 A1
(43) Pub. Date: Jan. 16, 2003

(54) Cold cathode device

(75) Inventor: Hiroo Hongo, Tokyo (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/191,477

(22) Filed: Jul. 10, 2002

(30) Foreign Application Priority Data
Jul. 16, 2001 (JP) 215958/2001

(51) Int. Cl. H01L 29/74; H01L 31/111

(52) U.S. Cl. 257/144

(57) ABSTRACT

A cold cathode device is formed from a p-type semiconductor substrate 1. Two source/drain regions 2 are formed in the p-type semiconductor substrate 1, a silicon oxide film 3, which is an insulating film, is formed on the surface of the p-type semiconductor substrate 1 (the face where the source/drain regions 2 are formed), and a gate electrode 4 is formed on top of the silicon oxide film 3. Furthermore, a substrate electrode 5 is formed on the back surface of the p-type semiconductor substrate 1. The same voltages are applied to the source/drain regions 2 and the gate electrode 4, and a lower voltage is applied to the substrate electrode 5.

This application is based on Japanese patent application NO.2001-215958, the content of which is incorporated hereinto by reference.

### BACKGROUND OF THE INVENTION

1. Field of the Invention

The present invention relates to a cold cathode device that emits electrons generated within a p-type semiconductor.

2. Description of the Related Art

FIG. 5 is a cross section showing an example of the structure of a general cold cathode device. The cold cathode device shown in FIG. 5 is formed from a semiconductor (n-type semiconductor) substrate 10, an insulating film 11 formed on the substrate 10 and comprising silicon oxide, etc., and a surface electrode layer (gate electrode) 12 formed on the insulating film 11. That is, the cold cathode device shown in FIG. 5 has the configuration semiconductor-insulator-metal. Instead of the semiconductor, a metal may be used in some cases. That is, the cold cathode device may have the configuration metal-insulator-metal.

The structure of a general cold cathode device such as that in FIG. 5 is also disclosed in, for example, The Journal of Vacuum Science and Technology, Vol. BII, pp. 429-432 (1993, published by the American Vacuum Society).

In the cold cathode device shown in FIG. 5, in order for electrons to be emitted from the surface electrode layer 12 into a vacuum, it is necessary for electrons present in the conduction band of the n-type semiconductor substrate 10 to pass through the insulator film 11 by means of the tunnel effect and be pulled out into the surface electrode layer 12. Further, in order for the electrons that have been pulled out to be emitted, it is necessary to make the energy of the electrons higher than the vacuum level (see FIG. 6). It is therefore necessary to apply a voltage between the surface electrode layer 12 and the semiconductor substrate 10 so that the surface electrode layer 12 becomes the positive side.

In the cold cathode device shown in FIG. 5, since electron emission is obtained by applying a voltage between the surface electrode layer 12 and the n-type semiconductor substrate 10, the insulating film 11 is subjected to a strong electric field when electrons are being emitted. However, it is known that injecting electrons into the insulating film 11 while it is subjected to a strong electric field shortens the lifetime of the insulating film 11. The influence of an applied voltage on the lifetime of an insulating film employing silicon oxide is described in, for example, IEEE Transactions on Electron Devices, Vol. ED-32, No. 2, pp. 413-422 (1985).

That is, (1) as shown in FIG. 7A, if electrons are injected from the n-type semiconductor substrate 10 into the insulating film 11 (silicon oxide film) while a strong electric field is being applied to the insulating film 11, these electrons are accelerated by the electric field. (2) The accelerated electrons have a high energy and excite electron-hole pairs within the insulating film 11 in the vicinity of the surface electrode layer 12. (3) The excited holes are captured by defects within the insulating film 11 while being attracted toward the semiconductor substrate 10 by the electric field, thereby generating a local electric field within the insulating film 11 as shown in FIG. 7B. (4) The local electric field so generated within the insulating film 11 reduces the effective thickness of the insulating film 11, and the number of electrons that are injected into the insulating film 11 thereby increases. (5) Since steps (1) to (4) form a positive feedback loop, a local electric field is built up within the insulating film 11 thereby generating a voltage that is higher than the withstand voltage of the insulating film 11, and the insulating film 11 thus breaks down. The higher the external voltage that is applied to the insulating film 11, the greater the probability of electron-hole pairs being generated within the insulating film 11.

As hereinbefore described, in the conventional cold cathode device, since a strong electric field is applied to the insulating film 11 (silicon oxide film), the holes of the electron-hole pairs generated by excitation are attracted toward the semiconductor substrate 10 by the electric field and at the same time the energy of the injected electrons increases. Since the holes that are attracted toward the semiconductor substrate 10 are easily captured, the local potential is lowered on the semiconductor substrate 10 side, and the reduction of the effective thickness of the oxide film becomes more apparent on this side than on the gate electrode side. Furthermore, since the electric field increases the energy of the electrons, the probability of electron-hole pairs being generated increases. As a result, the lifetime of the insulating film 11 is shortened.

### SUMMARY OF THE INVENTION

An object of the present invention is to provide a cold cathode device in which the device lifetime and operational stability are improved.

A first aspect of the present invention provides a cold cathode device that employs a p-type semiconductor as an electron source, electrons of electron-hole pairs generated by a strong electric field in the valence band within the p-type semiconductor being used for electron emission.

In accordance with the first aspect, since the electrons of the electron-hole pairs generated by the strong electric field in the valence band within the p-type semiconductor are used for electron emission, sufficient electrons can be emitted without applying a strong electric field to an insulating film, etc. directly beneath the surface electrode from which the electrons are emitted. It is therefore possible to increase the lifetime of the device as well as to improve the operational stability.

In the cold cathode device of the first aspect, the electrons of the electron-hole pairs generated by the strong electric field within the p-type semiconductor can be pulled from the valence band into the conduction band by interband tunneling and used for electron emission. In the cold cathode device of the first aspect, the concentration of p-type impurity in the p-type semiconductor can be, for example, 10¹⁵ to 10¹⁹ cm³.

Furthermore, a second aspect of the present invention provides a cold cathode device including a p-type semiconductor substrate, an insulating film formed on the surface of the p-type semiconductor substrate, and a surface electrode formed on the insulating film, electrons being emitted to the outside through the surface electrode.

In accordance with the second aspect, since electrons of electron-hole pairs generated in the valence band of the p-type semiconductor substrate are used for electron emission, sufficient electrons can be emitted without applying a strong electric field to the insulating film directly beneath the surface electrode from which the electrons are emitted. It is therefore possible to both increase the lifetime of the device and improve the operational stability.

As mentioned in the section ‘Description of the Related Art’, a conventional cold cathode device uses an n-type semiconductor substrate, and electrons present in the conduction band of the n-type semiconductor substrate pass through the insulating film by the tunneling effect and are emitted. Since it is necessary both for electrons to pass through the insulating film and for the energy of the emitted electrons to be made higher than the vacuum level, it is necessary in the prior art to apply a strong electric field to the insulating film. On the other hand, in accordance with the present invention, since the electrons are pulled from the valence band into the conduction band by interband tunneling and then emitted, sufficient electrons can be emitted by applying a strong electric field to the p-type semiconductor substrate, without exposing the insulating film to a strong electric field.

In the cold cathode device of the second aspect, there can be further included means for controlling the potential of the side of the insulating film that is in contact with the p-type semiconductor substrate. In this cold cathode device, the means for controlling the potential of the side of the insulating film that is in contact with the p-type semiconductor substrate can, for example, include a constitution having means for forming a channel region directly beneath the surface electrode while applying a voltage, and means for controlling the potential of the channel region.

In the cold cathode device of the second aspect, there can be further included a first n-type semiconductor region and a second n-type semiconductor region formed in the vicinity of the surface of the p-type semiconductor substrate so that the region directly beneath the surface electrode is sandwiched between the first and second n-type semiconductor regions, a first control electrode for controlling the potential of the first n-type semiconductor region, and a second control electrode for controlling the potential of the second n-type semiconductor region.

In accordance with this cold cathode device, n-type carriers are induced in the region sandwiched between the first and second n-type semiconductor regions, thereby forming an n-type channel. Since this channel is joined to the first n-type semiconductor region or the second n-type semiconductor region, the channel potential can be controlled by adjusting the potential of the first n-type semiconductor region or the second n-type semiconductor region. Controlling the channel potential in this way allows the potential of the side of the insulating film that is in contact with the p-type semiconductor substrate to be controlled, thereby suppressing generation of an electric field in the insulating film.

In this cold cathode device there is further included a substrate electrode formed on the back surface of the p-type semiconductor substrate, substantially equal voltage being applied to the surface electrode, the first control electrode, and the second control electrode, and a voltage being applied to the substrate electrode so that the potential in the region of the p-type semiconductor near the substrate electrode is higher than the potential in the region near said first and second control electrodes. The term “potential” as used herein is a static-electron potential, which is a potential for an electron.

Since the substantially equal potentials are applied to all of the surface electrode, the first control electrode, and the second control electrode, the potential of the side of the insulating film that is in contact with the p-type semiconductor substrate is substantially equal to the potential of the side of the insulating film that is in contact with the surface electrode, thereby suppressing generation of an electric field in the insulating film. Furthermore, since a predetermined voltage is applied between the surface electrode and the substrate electrode, electrons can be generated in the p-type semiconductor substrate and then emitted to the outside via the surface electrode.

In the cold cathode device of the second aspect, there are further included an n-type semiconductor region and a control electrode for controlling the potential of the n-type semiconductor region, the n-type semiconductor region being formed in an annular shape in the vicinity of the surface of the p-type semiconductor substrate so as to encompass the periphery of the region directly beneath the surface electrode.

In accordance with this cold cathode device, n-type carriers are induced in the region encompassed by the n-type semiconductor region, thereby forming an n-type channel. Since this channel is joined to the n-type semiconductor region, the channel potential can be controlled by adjusting the potential of the n-type semiconductor region. Controlling the channel potential in this way allows the potential of the side of the insulating film that is in contact with the p-type semiconductor substrate to be controlled, thereby suppressing generation of an electric field in the insulating film.

In this cold cathode device, there is further included a substrate electrode formed on the back surface of the p-type semiconductor substrate, substantially equal potentials being applied to the surface electrode and the control electrode, and a potential that is lower than the above-mentioned potentials being applied to the substrate electrode. Since the substantially equal potentials are applied to both the surface electrode and the control electrode, the potential of the side of the insulating film that is in contact with the p-type semiconductor substrate is substantially equal to the potential of the side of the insulating film that is in contact with the surface electrode, thereby suppressing generation of an electric field in the insulating film. Furthermore, since a predetermined voltage is applied between the surface electrode and the substrate electrode, electrons can be generated in the p-type semiconductor substrate and then emitted to the outside via the surface electrode.

In the cold cathode device of the second aspect, electrons of electron-hole pairs generated by a strong electric field in the valence band within the p-type semiconductor substrate can be used for electron emission. Moreover, in this cold cathode device, the electrons of the electron-hole pairs generated by the strong electric field within the p-type semiconductor can be pulled from the valence band to the conduction band by interband tunneling and used for electron emission.

In the cold cathode device of the second aspect, the concentration of p-type impurity in the p-type semiconductor is 1015 to 1019 cm⁻³. In this way, it is possible to effectively form a channel in the region directly beneath the surface electrode, and controlling the potential of the channel can suppress generation of an electric field in the insulating film, thereby controlling the curvature of the energy band in the semiconductor substrate.

With regard to a cold cathode device using a p-type semiconductor substrate, JP-A-6-162918 describes a device utilizing avalanche breakdown.

That is, JP-A-6-162918 discloses an invention related to a semiconductor electron-emitting device in which a reverse bias voltage is applied to a pn junction to cause avalanche breakdown in a p-type semiconductor region having a high carrier density thereby generating hot electrons, and the electrons are emitted via an electron emitting part. In particular, the publication discloses a semiconductor electron-emitting device wherein forming a p-type semiconductor having a low carrier density concentrically outside the high density p-type semiconductor region can efficiently cause avalanche breakdown.

However, JP-A-6-162918 does not disclose the arrangement shown in FIG. 5 that can reduce the load on the insulating film in the cold cathode device in which electrons present in the semiconductor substrate pass through the insulating film 11 by the tunneling effect and are pulled out toward the surface electrode.

In the present invention, since the cold cathode device is arranged so that the electrons of electron-hole pairs generated by a strong electric field in the valence band within a p-type semiconductor are used for electron emission, the load on the insulating film can be reduced, thereby increasing lifetime and improving stability of the device.

Furthermore, the cold cathode device has a constitution in which a source/drain region is formed in a semiconductor substrate, an insulating film is formed over the semiconductor substrate, a gate electrode layer for emitting electrons from the semiconductor substrate to the outside is provided over the insulating film, the same voltages are applied to the source/drain region and the gate electrode layer, and a voltage having a level that is lower than the above-mentioned level is applied to a semiconductor substrate electrode. It is therefore possible for electrons in the semiconductor substrate to be emitted without providing a difference in potential between the surface of the semiconductor substrate and the gate electrode. Accordingly, since no electric field is generated within the insulating film, it is possible to prevent breakdown of the insulating film by electrons injected into the insulating film.

Other objects, features and advantages of the present invention will become apparent upon consideration of the specification and the appended drawings.

### BRIEF DESCRIPTION OF THE DRAWINGS

FIG. 1 is a cross section showing one example of the constitution of the cold cathode device according to the present invention.

FIG. 2 is an energy band diagram showing an energy band state when voltage is applied to the cold cathode device shown in FIG. 1.

FIG. 3(a) to (d) is a process chart for explaining a fabrication process for the cold cathode device shown in FIG. 1.

FIG. 4 is a top view of another constitution of the cold cathode device according to the present invention.

FIG. 5 is a cross section showing one example of the constitution of a conventional cold cathode device.

FIG. 6 is an energy band diagram showing an energy band state of the cold cathode device shown in FIG. 5.

FIG. 7A and FIG. 7B are diagrams for explaining a process by which the insulating film breaks down when voltage is applied to the cold cathode device shown in FIG. 5.

### DETAILED DESCRIPTION OF THE PREFERRED EMBODIMENTS

The present invention can employ a structure in which a source/drain regions are formed in the p-type semiconductor substrate, an insulating film is provided over the semiconductor substrate, and a gate electrode layer for emitting electrons from the semiconductor substrate to the outside is provided on the insulating film.

The same voltages are applied to the source/drain region and the gate electrode layer, and the voltage applied to the semiconductor substrate is preferably lower than the above-mentioned voltages. In this way, a strong electric field can be generated in the semiconductor substrate, and as a result electrons in the valence band of the semiconductor substrate can be emitted from the gate electrode layer by interband tunneling. Furthermore, since generation of an electric field in the insulating film can be suppressed, it is possible to prevent the injected electrons from causing breakdown of the insulating film. A voltage of, for example, 0 V is applied to the source/drain region and the gate electrode layer, and a voltage of, for example, −5 to −30 V is applied to the semiconductor substrate.

The gate electrode layer may be formed from a polycrystalline or amorphous semiconductor contaminated with a metal or an impurity. By forming the gate electrode layer in this way, its conductivity can be enhanced.

With regard to a material forming the insulating film, as well as silicon oxide, it is possible to use a silicon-based material such as silicon nitride or silicon oxynitride, a fluorine-based material such as CaF₂, or a material known as a ‘high-k’ film material such as zirconium oxide, hafnium oxide, or aluminum oxide.

The semiconductor substrate, insulating film, and gate electrode layer may be formed by epitaxial growth. The semiconductor substrate, insulating film, and gate electrode layer can have, for example, a heteroepitaxial structure.

The impurity concentration in the source/drain region can be 10¹⁵ to 10¹⁹ cm⁻³. Setting the impurity concentration in the source/drain region in this range can reduce the contact resistance between the source/drain region and the source/drain electrode as well as prevent the crystallinity in the source/drain region from deteriorating.

Source/drain regions may be formed at two positions in the semiconductor substrate, and the gate electrode layer may be disposed at a position between the source/drain regions. By so doing, a channel can be formed in a region bounded by one source/drain region and the other source/drain region in the semiconductor substrate, and the voltage of the channel is controllable, thereby preventing generation of an electric field within the insulating film.

Alternatively, a toroidal source/drain region may be formed in the semiconductor substrate, and the gate electrode may be provided at a position surrounded by the source/drain region. This arrangement can also prevent the generation of an electric field within the insulating film.

The impurity concentration in the semiconductor substrate can be 10¹⁵ to 10¹⁹ cm⁻³. Setting the impurity concentration in the semiconductor substrate in this range can form a channel in a region bounded by one source/drain region and another source/drain region in the semiconductor substrate, and since the voltage of the channel is controllable, the curvature of the energy band in the semiconductor substrate can be controlled.

Next, an embodiment of the present invention is explained by reference to drawings. The following examples are provided to more clearly describe the invention and are in no manner to be deemed limiting on the full scope of the invention.

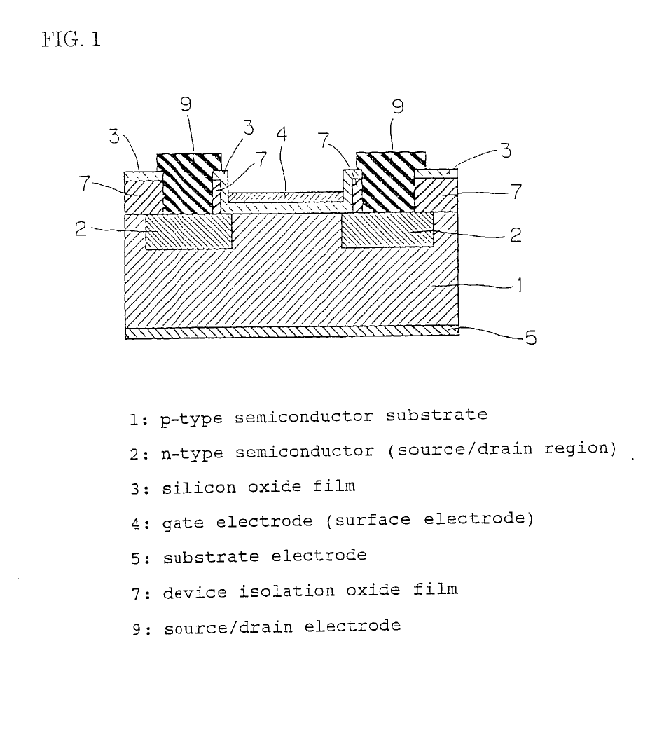

FIG. 1 is a cross section showing one example of the structure of the cold cathode device according to the present invention.

The cold cathode device shown in FIG. 1 is formed from a p-type semiconductor substrate 1, source/drain regions (n-type semiconductor) 2, a silicon oxide film 3, which is an insulating film, a gate electrode (surface electrode layer) 4, a substrate electrode 5, device isolation oxide film 7, and source/drain electrodes 9.

The source/drain regions 2 are formed at two positions in the upper part of the p-type semiconductor substrate 1. The substrate electrode 5 is in contact with the back surface of the p-type semiconductor substrate 1. The upper faces (surfaces) of the source/drain regions 2 are in contact with the source/drain electrodes 9. The side faces of the source/drain electrodes 9 are in contact with the device isolation oxide film 7. The height of the device isolation oxide film 7 is lower than that of the source/drain electrodes 9.

The lower face of the device isolation oxide film 7 is in contact with the upper face of the p-type semiconductor substrate 1. The upper face of the device isolation oxide film 7 is in contact with the silicon oxide film 3. The silicon oxide film 3 is in contact with the part of the upper face of the p-type semiconductor substrate 1 that is disposed between one source/drain region 2 and the other source/drain region 2. The upper face of the silicon oxide film 3 is in contact with the gate electrode 4. The silicon oxide film 3 is in contact with the part of the side face of the device isolation oxide film 7 that faces the side face of the gate electrode 4.

The p-type semiconductor substrate 1 is formed from a p-type Si semiconductor having an impurity concentration on the order of 1015 to 1019 cm⁻³. Setting the impurity concentration of the p-type semiconductor substrate 1 in this range can prevent the energy band in the p-type semiconductor substrate 1 from curving abruptly.

The source/drain region 2 is formed from an n-type silicon layer having an impurity concentration on the order of 10¹⁵ to 10¹⁹ cm⁻³. Setting the impurity concentration of the source/drain region 2 in this range can maintain a low contact resistance between the source/drain region 2 and the source/drain electrode 9. It is also possible to prevent the crystallinity of the source/drain region 2 from deteriorating. The device isolation oxide film 7 is formed from SiO₂, etc. with a thickness on the order of 150 nm, and is provided for the purpose of separating elements. The device isolation oxide film 7 can be formed by, for example, thermal oxidation.

The silicon oxide film 3 can be formed so as to have a film thickness on the order of 2 to 30 nm. The silicon oxide film 3 may be formed from the same material as that used for the device isolation oxide film 7. The gate electrode 4 is formed from a metal such as Pt or Au with a thickness on the order of 1 to 20 nm. The source/drain electrode 9 is a contact electrode. The substrate electrode 5 is an electrode formed from a metal such as Al or Au. The substrate electrode 5 is vapor deposited on the back surface of the p-type semiconductor substrate 1.

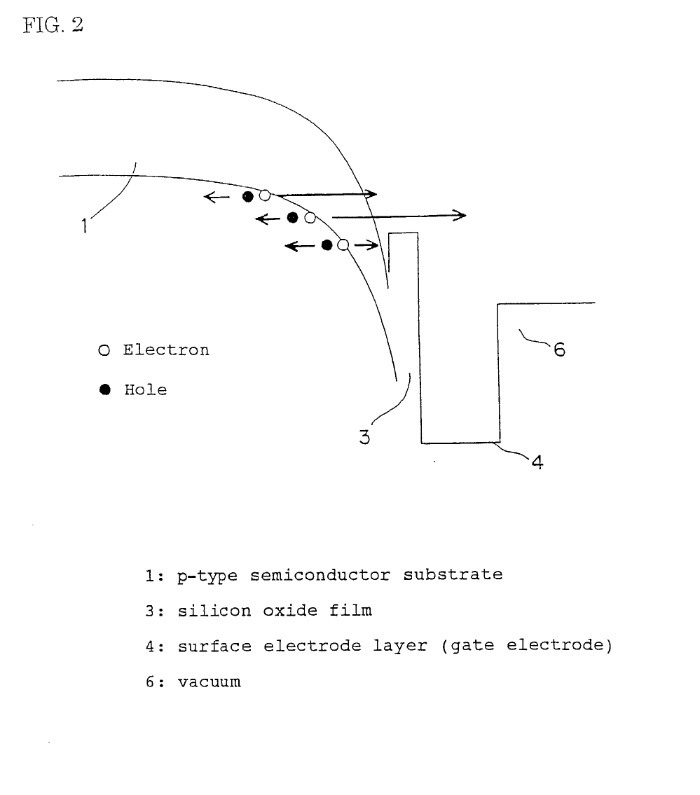

Next, the operation of electron emission in the cold cathode device shown in FIG. 1 is explained by reference to the energy band diagram shown in FIG. 2.

FIG. 2 shows an energy band state of a section beneath the gate electrode 4 when voltages are applied to the source/drain electrodes 9, the gate electrode 4, and the substrate electrode 5. That is, the energy band states in the p-type semiconductor substrate 1, the silicon oxide film 3, and the gate electrode 4 are shown together with the energy band state of vacuum 6 (vacuum level).

Here, the potentials of the source/drain electrodes 9 and the gate electrode 4 are 0 V, and a voltage on the order of −5 to −30 V is applied to the substrate electrode 5.

In order to operate the p-type semiconductor substrate 1 as an electron source, voltages are applied to the gate electrode 4, the substrate electrode 5, and the source/drain electrodes 9. In this case, the same voltages (for example, 0 V) are applied to the gate electrode 4 and the source/drain electrodes 9. As is the case with an MOS transistor, a channel can be formed in a region sandwiched between the source/drain regions 2 in the p-type semiconductor substrate 1, and the potential of the region is controllable. It is therefore possible to equalize the voltage level applied to the surface (the side in contact with the gate electrode 4) of the silicon oxide film 3 with that applied to the back surface (the side in contact with the p-type semiconductor substrate 1). A voltage on the order of −5 to −30 V is applied to the substrate electrode 5. As a result, a strong electric field is generated within the p-type semiconductor substrate 1 in a direction from the gate electrode 4 to the substrate electrode 5.

Within the p-type semiconductor substrate 1, electron-hole pairs are generated by the strong electric field in the part directly beneath the gate electrode 4. The holes are attracted toward the negatively biased substrate electrode 5. On the other hand, the electrons are attracted toward the gate electrode 4 by interband tunneling. That is, the electrons generated in the valence band by the strong electric field move to the conduction band by interband tunneling as shown by rightward arrows in FIG. 2, and are then pulled toward the gate electrode 4.

Electrons that are generated in an area sufficiently close to the gate electrode 4 are accelerated by the electric field and reach the silicon oxide film 3 while maintaining their energy. Electrons that have a higher energy than the height of the barrier of the silicon oxide film 3 move over the barrier of the silicon oxide film 3, pass through the gate electrode 4 while losing a part of their energy, and are emitted from the gate electrode 4 into vacuum. Alternatively, if the thickness of the silicon oxide film 3 is sufficiently small, electrons that have a lower energy than the height of the barrier of the silicon oxide film 3 can, although the probability is low, tunnel through the silicon oxide film 3, pass through the gate electrode 4 while losing a part of their energy, and be emitted from the gate electrode 4 into vacuum.

In this case, the voltage applied to the substrate electrode 5 is preferably controlled so that the energy, relative to the end of the conduction band of the silicon oxide film 3, of electrons injected into the silicon oxide film 3 is smaller than the band gap energy (about 9 eV) of the silicon oxide film 3. By so doing, the rate of generation of the electron-hole pairs in the silicon oxide film 3 can be further decreased.

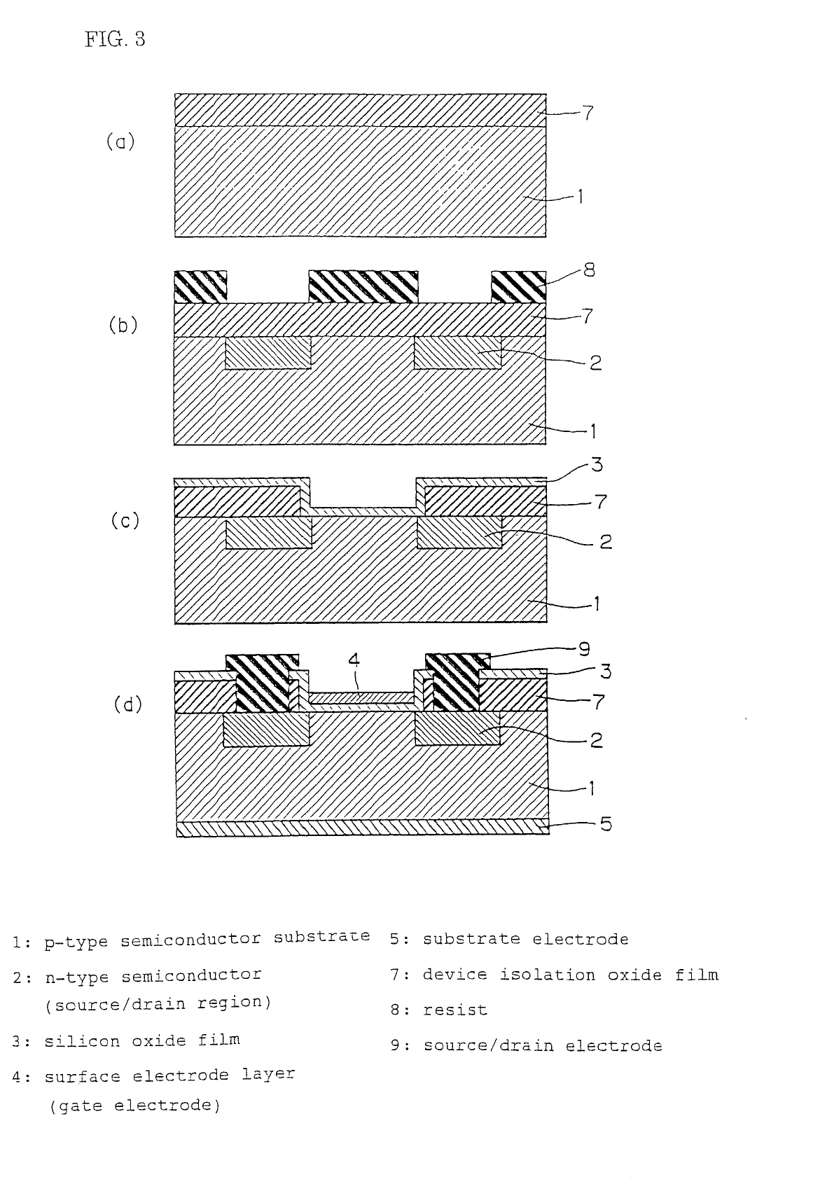

Next, a process for fabricating the cold cathode device shown in FIG. 1 is explained by reference to FIG. 3. FIG. 3 is a process chart for explaining the fabrication process for the cold cathode device shown in FIG. 1.

As the device isolation oxide film 7, SiO₂ with a thickness on the order of 150 nm is formed on the upper face of the p-type semiconductor substrate 1 having an impurity concentration on the order of 10¹⁵ to 10¹⁹ cm⁻³ (see FIG. 3A). The device isolation oxide film 7 is formed by thermal oxidation. The upper face of the device isolation oxide film 7 is coated with a resist 8 and subjected to a step involving dry etching, etc. The p-type semiconductor substrate 1 is then subjected to ion doping (ion implantation), etc. to form the source/drain regions 2 as is the case with the fabrication of a field-effect transistor (see FIG. 3B). In this stage, it is desirable for the impurity concentration of the source/drain region 2 to be on the order of 10¹⁵ to 10¹⁹ cm⁻³ in order to lower the contact resistance between the source/drain region 2 and the source/drain electrode 9. Next, in order to form the device isolation oxide film 7, SiO₂ with a thickness on the order of 150 nm is reformed on the surface of the source/drain region 2 by thermal oxidation, etc.

Wet etching is then carried out so as to remove a part (electron emission part) of the device isolation oxide film 7, the part being sandwiched between the two source/drain regions 2. A silicon oxide film 3 with a thickness on the order of 2 to 30 nm is formed by thermal oxidation, etc. on parts (the upper and side faces of the device isolation oxide film 7 and the upper face of the p-type semiconductor substrate 1) that are exposed when the p-type semiconductor substrate 1 is viewed from above (see FIG. 3C).

Furthermore, contact holes for embedding the source/drain electrodes 9 are formed by wet etching in parts of the device isolation oxide film 7 and the silicon oxide film 3 above the source/drain regions 2, and the source/drain electrodes 9 are then formed in the contact holes. As the gate electrode 4, a metal such as Pt or Au with a thickness on the order of 1 to 30 nm is formed on the surface of the electron emission part of the silicon oxide film 3. Moreover, a metal such as Al or Au is vapor deposited on the back surface of the p-type semiconductor substrate 1 to form the substrate electrode 5 (see FIG. 3D). Alternatively, the gate electrode 4 may be formed prior to formation of the source/drain electrode 9.

As hereinbefore described, in accordance with the present embodiment, the cold cathode device shown in FIG. 1 can be fabricated via the steps shown in FIGS. 3A to 3D.

In the arrangement of the present invention where the p-type semiconductor substrate 1 is used as an electron source, the band structure can be designed as shown in FIG. 2 so that the energy of the emitted electrons is higher than the barrier of the silicon oxide film 3. As a result, the electrons that have moved from the valence band to the conduction band by interband transition can be emitted outside the device as they are, and in this case there is no need to generate an electric field in the silicon oxide film 3.

That is, since no electric field is generated within the silicon oxide film 3, electrons can be injected into the silicon oxide film 3 in a state in which the electrons are not accelerated in the silicon oxide film 3. Hence, the energy of the electrons injected into the silicon oxide film 3 does not increase, thereby reducing to a low level the probability of electron-hole pairs being excited within the silicon oxide film 3.

Furthermore, since no electric field is generated within the silicon oxide film 3 and the probability of electron-hole pairs being excited is reduced to a low level, it is possible to prevent a local electric field from being generated within the silicon oxide film 3, the local electric field being caused by defects capturing the excited holes while they are being attracted toward the p-type semiconductor substrate 1 as is the case with a conventional cold cathode device. That is, it is possible to prevent a voltage that is higher than the withstand voltage of the silicon oxide film 3 from being generated. As a result, the load on the silicon oxide film 3 can be reduced, thereby increasing the lifetime of the silicon oxide film 3 and improving the stability.

Although the above-mentioned embodiment illustrates an example in which the silicon oxide film 3 is used as the insulating film, another insulating material can be used to form the insulating film. For example, an aluminum oxide film (Al₂O₃, etc.) can be used as the insulating film. Furthermore, the gate electrode 4 can be formed using an amorphous semiconductor or a polycrystalline semiconductor. In this case, it is desirable to introduce an impurity into the gate electrode 4 to impart conductivity thereto. Moreover, in the example illustrated above the p-type semiconductor substrate 1 is used as the semiconductor substrate, but a semiconductor substrate using a semiconductor other than silicon may be employed.

Furthermore, the semiconductor substrate, insulating layer, and gate electrode layer can be formed by heteroepitaxial growth of a compound semiconductor such as GaAs/AlGaAs or InP/GaInAs. That is, a single crystal semiconductor obtained by heteroepitaxial growth may be used. It is desirable to use as the gate electrode layer an n-type semiconductor into which a high concentration (on the order of 10¹⁶ cm⁻³) of impurity has been introduced in order to reduce the resistance of the electrode. It is also desirable for the thickness thereof to be on the order of 100 nm or below.

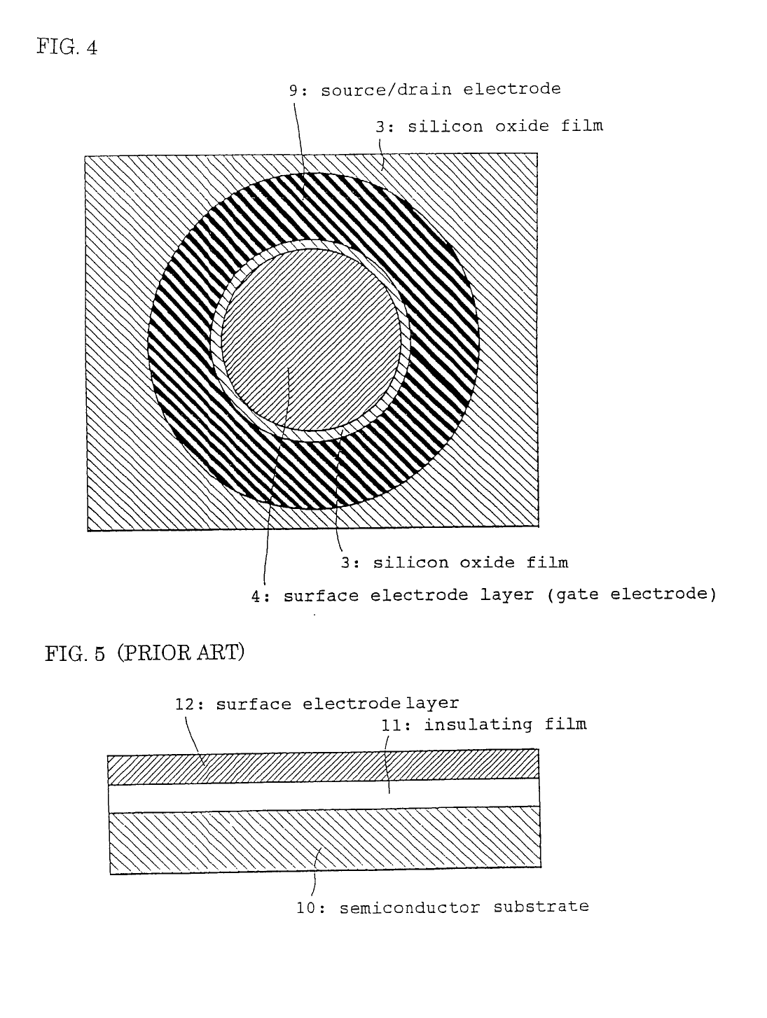

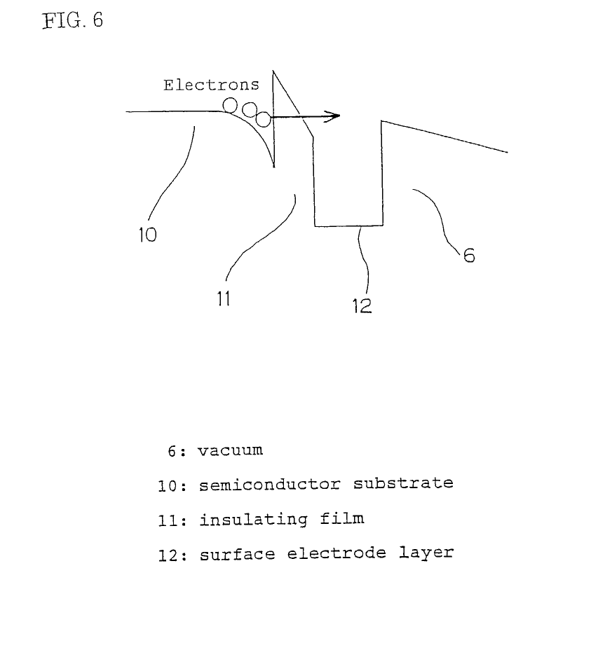

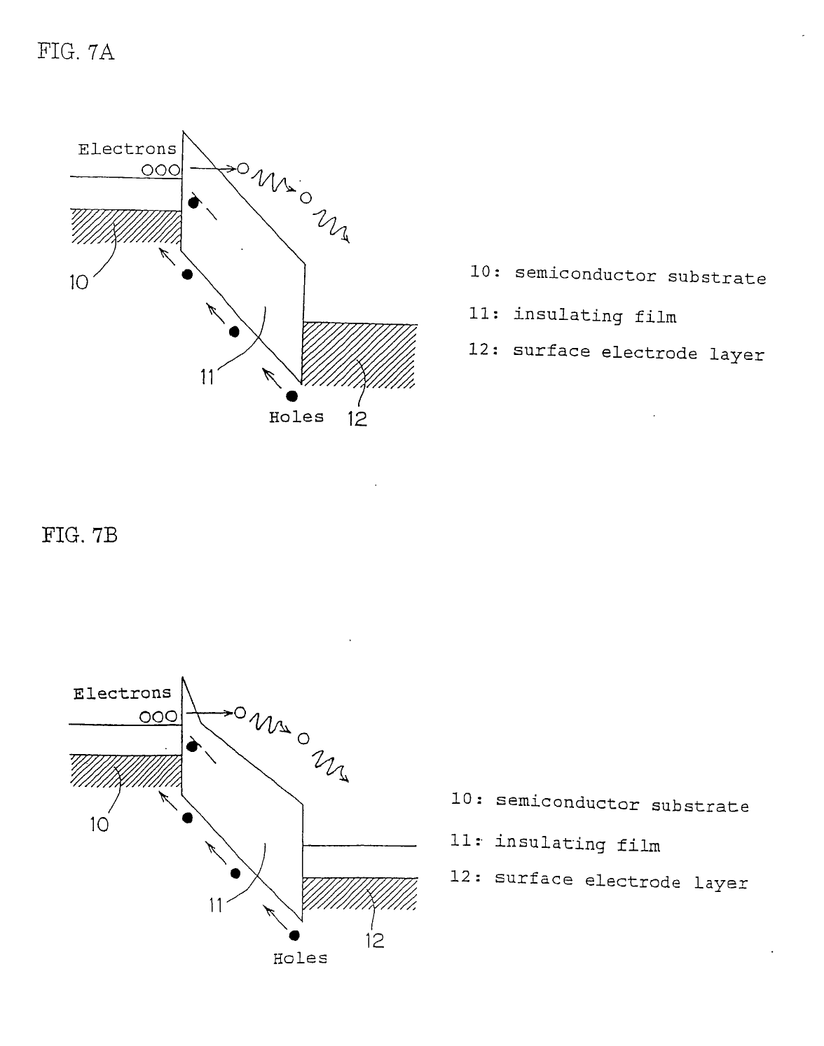

Although the above-mentioned embodiment illustrates an example in which two source/drain regions 2 (source/drain electrodes 9) are formed in the p-type semiconductor substrate 1, the source/drain electrode 9 may be formed in a toroidal shape as shown in FIG. 4 on the p-type semiconductor substrate 1. Furthermore, the shape of the source/drain electrode 9 is not limited to the toroidal shape. For example, the source/drain electrode 9 may have a polygonal shape such as hexagonal or octagonal. By so doing, the degree of integration of the cold cathode device can be increased.

While the invention has been described by reference to different embodiments, it will be understood that various changes and modifications may be made without departing from the scope of the invention which is to be defined only by the appended claims and their equivalent.

What is claimed is:

1. A cold cathode device comprising:
a p-type semiconductor as an electron source, electrons of electron-hole pairs generated by a strong electric field in the valence band within the p-type semiconductor being used for electron emission.

2. The cold cathode device according to claim 1 wherein the electrons of the electron-hole pairs generated by the strong electric field within the p-type semiconductor are pulled from the valence band into the conduction band by interband tunneling and used for electron emission.

3. The cold cathode device according to claim 1 wherein the concentration of p-type impurity in the p-type semiconductor is 10¹⁵ to 10¹⁹ cm⁻³.

4. A cold cathode device comprising:
a p-type semiconductor substrate;
an insulating film formed on the surface of the p-type semiconductor substrate; and
a surface electrode formed on the insulating film, electrons being emitted to the outside through the surface electrode.

5. The cold cathode device according to claim 4 further comprising:
means for controlling the potential of the side of the insulating film that is in contact with the p-type semiconductor substrate.

6. The cold cathode device according to claim 5 wherein the means for controlling the potential of the side of the insulating film that is in contact with the p-type semiconductor substrate comprises means for forming a channel region directly beneath the surface electrode while applying a voltage, and means for controlling the potential of the channel region.

7. The cold cathode device according to claim 4 further comprising:
a first n-type semiconductor region and a second n-type semiconductor region formed in the vicinity of the surface of the p-type semiconductor substrate so that the region directly beneath the surface electrode is sandwiched between the first and second n-type semiconductor regions;
a first control electrode for controlling the potential of the first n-type semiconductor region; and
a second control electrode for controlling the potential of the second n-type semiconductor region.

8. The cold cathode device according to claim 7 further comprising:
a substrate electrode formed on the back surface of the p-type semiconductor substrate, substantially equal voltage being applied to the surface electrode, the first control electrode, and the second control electrode, and a voltage being applied to the substrate electrode so that the potential in the region of the p-type semiconductor near the substrate electrode is higher than the potential in the region near said first and second control electrodes.

9. The cold cathode device according to claim 4 further comprising:
an n-type semiconductor region formed in an annular shape in the vicinity of the surface of the p-type semiconductor substrate so as to encompass the periphery of the region directly beneath the surface electrode; and
a control electrode for controlling the potential of the n-type semiconductor region.

10. The cold cathode device according to claim 9 further comprising:
a substrate electrode formed on the back surface of the p-type semiconductor substrate, substantially equal potentials being applied to the surface electrode and the control electrode, and a potential that is lower than the above-mentioned potentials being applied to the substrate electrode.

11. The cold cathode device according to claim 4 wherein electrons of electron-hole pairs generated by a strong electric field in the valence band within the p-type semiconductor substrate are used for electron emission.

12. The cold cathode device according to claim 11 wherein the electrons of the electron-hole pairs generated by the strong electric field within the p-type semiconductor are pulled from the valence band to the conduction band by interband tunneling and used for electron emission.

13. The cold cathode device according to claim 4 wherein the concentration of p-type impurity in the p-type semiconductor is 10¹⁵ to 10¹⁹ cm⁻³.
